(19) United States
(12) Patent Application Publication
(10) Pub. No.: US 2004/0165471 A1
(43) Pub. Date: Aug. 26, 2004

(54) Semiconductor device

(76) Inventors: Sadayuki Morita, Higashiyamato (JP); Yoshikazu Saitou, Hamura (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/768,157

(22) Filed: Feb. 2, 2004

(30) Foreign Application Priority Data
Feb. 25, 2003 (JP) 2003-047071

(51) Int. Cl. G11C 5/00

(52) U.S. Cl. 365/230.08

(57) ABSTRACT

The semiconductor device of the invention achieves a high-speed memory access. When the semiconductor device is configured to include a microprocessor and a semiconductor memory, the microprocessor includes an input/output buffer for system side that is made capable of exchanging signals with the outside by being supplied with a power supply voltage. The semiconductor memory includes an internal power supply circuit that takes in the power supply voltage as a reference voltage, and generates an internal power supply voltage being substantially equal to the power supply voltage; and it also includes an input/output buffer for memory side that is made capable of exchanging signals with the input/output buffer for system side by being supplied with the internal power supply voltage. This circuit configuration saves the level shifting on the microprocessor side, and realizes a high-speed access to the semiconductor memory from the microprocessor.

### BACKGROUND OF THE INVENTION

The present invention relates to a semiconductor device, specifically to a technique effective in use for a multi-chip module in which plural semiconductor chips are mounted and assembled on a common wiring substrate.

A multi-chip module technique such that plural LSI chips such as a microprocessor and a memory are mounted on a common wiring substrate to build up a small computer system (for example, refer to Patent Document 1) has been widespread in recent years.

The multi-chip module technique, using a printed substrate patterned in advance or a ceramic substrate as a common wiring substrate, disposes plural bare LSI chips on this common wiring substrate, and bonds pad electrodes of the LSI chips to patterns (conductive layers) on the wiring substrate by means of the wire bonding, the flip chip method, or the like, thus packaging a computer system. The plural bare LSI chips can be disposed two-dimensionally in a plane, or they can be stacked up. As an example in which the plural bare LSI chips are stacked up, a module can be quoted which mounts an SRAM (Static Random Access Memory) to overlie a mobile system LSI with a large capacity SRAM eliminated.

There is a well-known technique that appropriately converts a signal level outputted from a signal output circuit without using external components such as pull-up resistors, and transmits the converted level to an external circuit driven by a voltage different from the voltage of the signal output circuit. In this case, on the final output stage of an LSI driven by the driving power supply voltage of 5 volts except for the final output stage, there are laid out inverter gates supplied with a driving power supply voltage independently from the above driving power supply voltage. The output signal of the LSI is supplied to a power supply input terminal of the inverter gates, and the driving power supply voltage of the LSI is connected by way of the power supply lines (for example, refer to Patent Document 2).

[Patent Document 1]

Japanese Umexamined Patent Publication No. Hei 9(1997)-331016

[Patent Document 2]

Japanese Umexamined Patent Publication No. Hei 11(1999)-41089

### SUMMARY OF THE INVENTION

In contrast to a single chip microprocessor for the mobile equipment that incorporates a large capacity SRAM, in the multi-chip module in which a universal SRAM of low power consumption is mounted to overlie the microprocessor for the mobile equipment with the large capacity SRAM eliminated, each chip has two kinds of voltages of the core voltage and the interface voltage. Therefore, when exchanging signals between the microprocessor and the external SRAM, the multi-chip module executes the level shifting of the signals each individually in the I/O of the microprocessor and in the I/O of the SRAM chip to consequently obstruct speeding up memory accesses, which the inventor of this application discovers.

The present invention has been made in view of the above technical problems, and an object of the invention is to provide a technique that permits to speed up memory accesses in a semiconductor device.

The foregoing and other objects and the novel features of the invention will become apparent from the descriptions and appended drawings of this specification.

The typical invention disclosed in the present invention will be briefly described below.

According to one aspect of the invention, the semiconductor device includes a microprocessor and a semiconductor memory. Here, the microprocessor includes an input/output buffer for system side that is made capable of exchanging signals with the outside by being supplied with a power supply voltage. The semiconductor memory includes an internal power supply circuit that takes in the power supply voltage as a reference voltage, and generates an internal power supply voltage being substantially equal to the power supply voltage. The semiconductor memory also includes an input/output buffer for memory side that is made capable of exchanging signals with the input/output buffer for system side by being supplied with the internal power supply voltage.

The above means takes the power supply voltage for the microprocessor into the semiconductor memory as the reference voltage, and supplies the internal power supply voltage generated on the basis of the reference voltage to the input/output buffer for memory side, which makes it possible to match the signal level of the input/output buffer for memory side with that of an input/output buffer for system side. This saves the level shifting on the microprocessor side, which attains a high-speed access to the semiconductor memory from the microprocessor.

Here, the semiconductor memory may include a dedicated external terminal for taking in the power supply voltage as the reference voltage. Further, the microprocessor may include internal circuits that are put in operation by being supplied with the power supply voltage. In order to simply configure the internal power supply circuit, it is preferred to include a differential circuit that compares the power supply voltage taken in and an output voltage of the internal power supply circuit, and a voltage output circuit that determines a level of the internal power supply voltage on the basis of a comparison result in the differential circuit.

The semiconductor memory may include a memory internal circuit that is put in operation by being supplied with a second internal power supply voltage of a higher level than the internal power supply voltage; and the input/output buffer for memory side may include a level shifting circuit capable of shifting a signal level of the internal power supply voltage into a signal level of the second internal power supply voltage.

The semiconductor memory may include a step-down circuit that generates a third internal power supply voltage of a lower level than the internal power supply voltage, and a memory internal circuit that is put in operation by being supplied with the third internal power supply voltage; and the input/output buffer for memory side may include a level shifting circuit capable of shifting a signal level of the third internal power supply voltage into a signal level of the internal power supply voltage.

According to another aspect of the invention, the microprocessor includes an internal core power supply circuit that steps down a power supply voltage externally supplied to thereby generate an internal core power supply voltage, and an input/output buffer for system side that is made capable of exchanging signals with the outside by being supplied with the internal core power supply voltage. The semiconductor memory includes an internal power supply circuit that takes in the internal core power supply voltage as a reference voltage, and generates an internal power supply voltage being substantially equal to the internal core power supply voltage; and an input/output buffer for memory side that is made capable of exchanging signals with the input/output buffer for system side by being supplied with the internal power supply voltage.

When the semiconductor memory is of a clock synchronous type, the microprocessor may include a clock driver capable of outputting a clock signal; and the semiconductor memory may include a clock buffer that takes in the clock signal outputted through the clock driver in the microprocessor, and a logic circuit that operates synchronously with the clock signal taken in through the clock buffer.

The microprocessor and the semiconductor memory may each be formed in separate chips, and these chips may integrally be packaged in a resin mold.

### BRIEF DESCRIPTION OF THE DRAWINGS

FIG. 1 illustrates a circuit configuration of the major part in the multi-chip module as an example of the semiconductor device relating to the invention;

FIG. 2 is a perspective view of the above multi-chip module;

FIG. 3 is a block diagram of the microprocessor included in the multi-chip module;

FIG. 4 is a block diagram of the SRAM included in the multi-chip module;

FIG. 5 illustrates another circuit configuration of the major part in the multi-chip module;

FIG. 6 is a perspective view of another multi-chip module being an example of the semiconductor device relating to the invention;

FIG. 7 illustrates a circuit configuration of the major part in the multi-chip module illustrated in FIG. 6; and

FIG. 8 illustrates another circuit configuration of the major part in the multi-chip module.

### DETAILED DESCRIPTION OF THE PREFERRED EMBODIMENTS

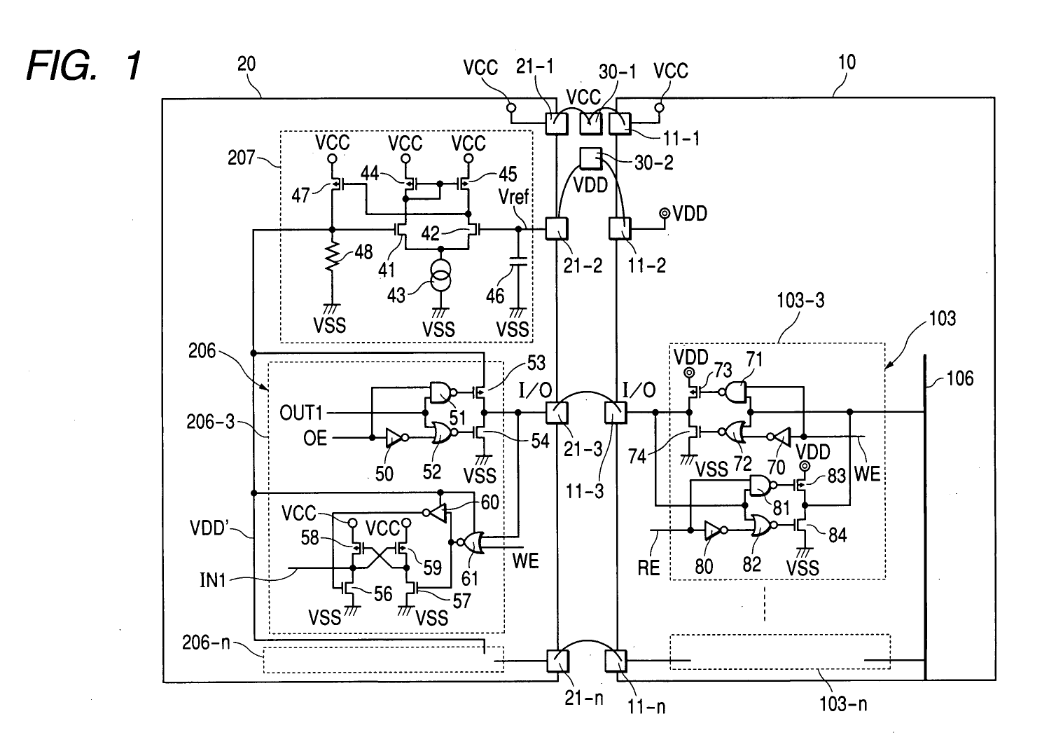

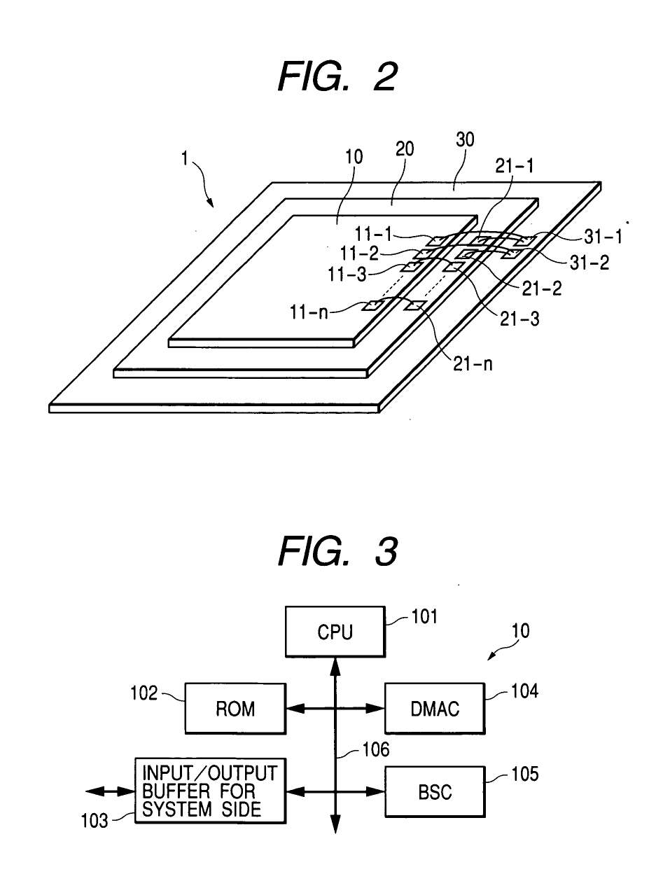

FIG. 2 illustrates the multi-chip module being an example of the semiconductor device relating to the invention. The multi-chip module 1 illustrated in FIG. 1 includes a microprocessor 10 named also as a system LSI, an SRAM (Static Random Access Memory) 20 capable of being accessed by the microprocessor 10, and a substrate 30 that mounts the former two, which is not specifically restricted; and these are integrally packaged by means of the resin molding. The microprocessor 10, SRAM 20, and substrate 30 each have bonding pads 11-1 to 11-n, 21-1 to 21-n, 31-1 to 31-2 formed thereon. By bonding these pads with bonding wires, the signal exchanges and power supply become possible. The SRAM 20 is used as work areas and the like in the processing of the microprocessor 10. Accordingly, the microprocessor 10 does not contain an SRAM being used as work areas and the like.

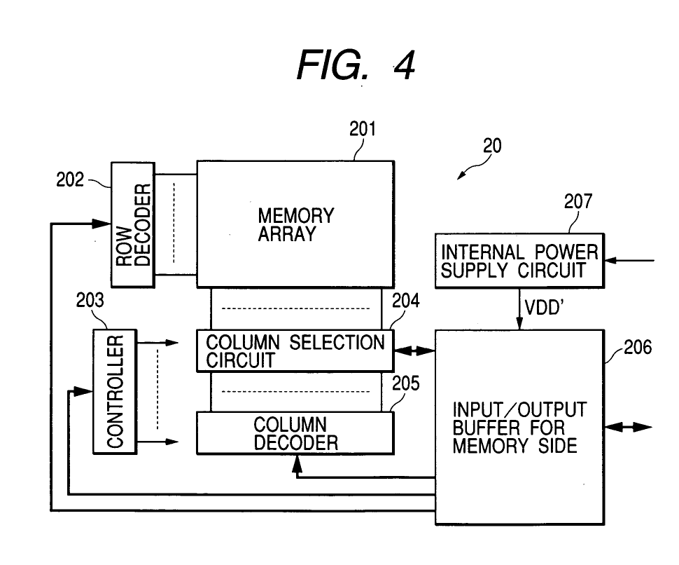

FIG. 3 illustrates a block diagram of the microprocessor 10.

As shown in FIG. 3, the microprocessor 10 includes a central processing unit (CPU) 101, read only memory (ROM) 102, input/output buffer 103 for system side, direct memory access controller (DMAC) 104, and bus state controller (BSC) 105, which is not specifically restricted; and these components are formed on one semiconductor substrate such as a single crystal silicon substrate by means of the well-known manufacturing method of semiconductor integrated circuits. The CPU 101, ROM 102, input/output buffer 103 for system side, DMAC 104, and BSC 105 are coupled by way of a bus 106 to be able to exchange signals between them.

The ROM 102 holds programs executed by the CPU 101. The input/output buffer 103 for system side permits to exchange various signals with the outside through the bonding pads, which is described in detail later. Especially, the CPU 101 is able to access the SRAM 20 through the input/output buffer 103 for system side. The DMAC 104 controls the DMA transfer between the memories not illustrated inside and outside the chip, and between integrated peripheral modules. The BSC 105 controls the bus state, for example, insertion of the wait cycle.

FIG. 4 illustrates a block diagram of the SRAM 20.

As shown in FIG. 4, the SRAM 20 includes a memory cell array 201, row decoder 202, controller 203, column selection circuit 204, column decoder 205, input/output buffer 206 for memory side, and internal power supply circuit 207, which is not specifically restricted; and these components are formed on one semiconductor substrate such as a single crystal silicon substrate by means of the well-known manufacturing method of semiconductor integrated circuits.

The memory cell array 201 includes plural word lines, plural bit lines disposed to intersect the word lines, plural static-type memory cells disposed on the intersecting points of the word lines and the bit lines. The row decoder 202 decodes row address signals, and thereby generates a signal for driving one word line among the plural word lines to the selection level. The column selection circuit 204 includes plural column selection switches for connecting the plural bit lines selectively to a common line. The column decoder 205 decodes column address signals, and thereby generates a driving signal for the column selection switches. The input/output buffer 206 for memory side includes an output circuit that externally outputs data of the common line, and an input circuit that fetches write data to the memory cell array 201 from the outside. The controller 203 generates timing signals for operating the related parts according to the control signals supplied from the outside. The internal power supply circuit 207 takes in the power supply voltage used in the microprocessor 10 as the reference voltage, and generates an internal power supply voltage VDD′. The internal power supply voltage VDD′ is supplied mainly to the input/output buffer 206 for memory side.

FIG. 1 illustrates the major part in the microprocessor 10 and the major part in the SRAM 20.

In the microprocessor 10, the bonding pads 11-1 and 11-2 are bonded respectively to the bonding pads 30-1 and 30-2 on the substrate 30, which make it possible to take in a high potential power supply voltage VCC and a high potential power supply voltage VDD. The high potential power supply voltage VCC is set to 3.3 V, and the high potential power supply voltage VDD is set to 1.5 V, which is not specifically restricted. The high potential power supply voltage VDD is supplied to the core parts in the microprocessor 10, such as the CPU 101, ROM 102, input/output buffer 103 for system side, DMAC 104, BSC 105, etc. Here, the low potential power supply voltage VSS (ground level) is defined as the Low level of the signals exchanged between the CPU 101, ROM 102, input/output buffer 103 for system side, DMAC 104, and BSC 105; and the high potential power supply voltage VDD (1.5 V) is defined as the High level.

The plural bonding pads 11-3 to 11-n are bonded to the plural bonding pads 21-3 to 21-n in the SRAM 20 by means of the wire bonding.

The input/output buffer 103 for system side includes plural input/output buffers 103-3 to 103-n corresponding to the plural bonding pads 11-3 to 11-n. The input/output buffer 103-3 being one of them is configured as follows.

When coupling a NAND gate 71 that attains the negative AND between a logic of specific bits of the bus 106 and a write enabling signal WE, a p-channel MOS transistor 73 whose operation is controlled by an output signal from the NAND gate 71, an inverter 70 that inverts a logic of the write enabling signal WE showing the validity of write data into the SRAM 20, a NOR gate 72 that attains the negative OR between an output signal from the inverter 70 and the logic of specific bits of the bus 106, and an n-channel MOS transistor 74 whose operation is controlled by an output signal from the NOR gate 72, the output buffer is formed that transmits the logic of specific bits of the bus 106 to the bonding pad 11-3 within a period where the write enabling signal WE is asserted to the High level. When coupling a NAND gate 81 that attains the negative AND between a logic of the bonding pad 11-3 and a read enabling signal RE showing the validity of readout data from the SRAM 20, a p-channel MOS transistor 83 whose operation is controlled by an output signal from the NAND gate 81, an inverter 80 that inverts a logic of the read enabling signal RE, a NOR gate 82 that attains the negative OR between an output signal from the inverter 80 and the logic of the bonding pad 11-3, and an n-channel MOS transistor 84 whose operation is controlled by an output signal from the NOR gate 82, the input buffer is formed that transmits the logic of the bonding pad 11-3 to the bus 106 within a period where the read enabling signal RE is asserted to the High level.

In the period where the read enabling signal RE is negated to the Low level, both the MOS transistors 83 and 84 are turned into OFF, whereby the output impedances thereof are turned into a high impedance to the bus 106.

The input/output buffer 103-n corresponding to the other bonding pad 11-n is also configured in the same manner as the above input/output buffer 103-3.

In case of the address signals and the various control signals, the signals are outputted only from the microprocessor 10 to the SRAM 20, and they will not be taken in from the SRAM 20 to the microprocessor 10. Therefore, the microprocessor 10 may eliminate the input buffers and possess only the output buffers, in regard to the buffers corresponding to the terminals (pads) of the address signals and various control signals.

According to the input/output buffer 103 for system side thus configured, while the write enabling signal WE is asserted to the High level, the signal of the bus 106 can be transmitted to the SRAM 20 through the bonding pads 11-3 to 11-n. While the read enabling signal RE is asserted to the High level, the signal transmitted from the SRAM 20 can be taken in through the bonding pads 11-3 to 11-n, and the taken-in signal can be transmitted to the bus 106.

Next in the SRAM 20, the bonding pads 21-1 and 21-2 are bonded respectively to the bonding pads 30-1 and 30-2 on the substrate 30, so that the high potential power supply voltage VCC and the high potential power supply voltage VDD can be taken in. The high potential power supply voltage VCC is supplied to the controller 203, row decoder 202, column decoder 205, and internal power supply circuit 207 and so forth. The high potential power supply voltage VDD is taken into the internal power supply circuit 207 as the reference voltage.

The internal power supply circuit 207 takes in the high potential power supply voltage VDD as the reference voltage Vref, which is transmitted through the bonding pad 21-2 (this high potential power supply voltage VDD is also supplied to the input/output buffer 103 for system side in the microprocessor 10), and generates the internal power supply voltage VDD′. Here, the potential level of the internal power supply voltage VDD′ is made substantially equal to that of the high potential power supply voltage VDD. The internal power supply circuit 207 is configured as follows.

The internal power supply circuit 207 is provided with a capacitor 46 that removes the noise components contained in the high potential power supply voltage VDD transmitted through the bonding pad 21-2. The high potential power supply voltage VDD is transmitted to the gate electrode of an n-channel MOS transistor 42. An n-channel MOS transistor 41 is differentially coupled with the n-channel MOS transistor 42. The drain electrodes of the MOS transistors 41, 42 are connected to a load of the current mirror configured with p-channel MOS transistors 44, 45, which are connected to the high potential power supply voltage VCC. The source electrodes of the MOS transistors 41, 42 are connected to the low potential power supply voltage VSS through a constant current source 43. The drain electrode of the MOS transistor 42 gives an output signal of the differential pair. The output signal of the differential pair is transmitted to the gate electrode of the p-channel MOS transistor 47. The source electrode of the p-channel MOS transistor 47 is connected to the high potential power supply voltage VCC, and the drain electrode of the p-channel MOS transistor 47 is connected to the low potential power supply voltage VSS through a resistor 48. The current flowing through the resistor 48 is controlled according to the output signal of the differential pair, whereby the level of the output voltage VDD′ of the internal power supply circuit 207 is determined. In this sense, the series circuit of the p-channel MOS transistor 47 and the resistor 48 is called the voltage output circuit. The output voltage VDD′ of the internal power supply circuit 207 is transmitted to the gate electrode of the MOS transistor 41, whereby the differential pair of the MOS transistors 41, 42 produces a difference of the high potential power supply voltage VDD and the output voltage VDD′ of the internal power supply circuit 207. Based on this difference, the current flowing through the resistor 48 is controlled by the MOS transistor 47, whereby the output voltage VDD′ of the internal power supply circuit 207 is controlled substantially equal to the high potential power supply voltage VDD. The output voltage VDD′ of the internal power supply circuit 207 is supplied to the input/output buffer 206 for memory side.

The input/output buffer 206 for memory side includes plural input/output buffers 206-3 to 206-n corresponding to the plural bonding pads 21-3 to 21-n. The input/output buffer 206-3 being one of them is configured as follows.

When coupling a NAND gate 51 that attains the negative AND between an output signal OUT1 and an output enabling signal OE, a p-channel MOS transistor 53 whose operation is controlled by an output signal from the NAND gate 51, an inverter 50 that inverts a logic of the output enabling signal OE, a NOR gate 52 that attains the negative OR between an output signal from the inverter 50 and the output signal OUT1, and an n-channel MOS transistor 54 whose operation is controlled by an output signal from the NOR gate 52, the input/output buffer 206-3 forms the output buffer that transmits the output signal OUT1 to the bonding pad 21-3 within a period where the output enabling signal OE is asserted to the High level. Although the high potential power supply voltage VCC is supplied to the NAND gate 51, inverter 50, and NOR gate 52, since the internal power supply voltage VDD′ is supplied to the source electrode of the p-channel MOS transistor 53, the High level of the output signal from the input/output buffer 206-3 is equal to the level of the internal power supply voltage VDD′, which is substantially equal to the level of the high potential power supply voltage VDD.

A NOR gate 61 attains the negative OR between a signal of the bonding pad 21-3 and the write enabling signal WE, and a post-stage level shifting circuit converts the level of the output signal from the NOR gate 61 into that of the high potential power supply voltage VCC. The level shifting circuit is configured to include an inverter 60 that inverts a logic of the output signal from the NOR gate 61, p-channel MOS transistors 58, 59, and n-channel MOS transistors 56, 57. The p-channel MOS transistor 58 and the n-channel MOS transistor 56 are connected in series, and the p-channel MOS transistor 59 and the n-channel MOS transistor 57 are connected in series. The source electrodes of the p-channel MOS transistors 58, 59 are connected to the high potential power supply voltage VCC, and the source electrodes of the n-channel MOS transistors 56, 57 are connected to the low potential power supply voltage VSS. The series connection node of the p-channel MOS transistor 58 and the n-channel MOS transistor 56 is connected to the gate electrode of the p-channel MOS transistor 59, and also connected to an internal circuit contained in the SRAM 20. The series connection node of the p-channel MOS transistor 59 and the n-channel MOS transistor 57 is connected to the gate electrode of the p-channel MOS transistor 58. The output signal from the NOR gate 61 is transmitted to the gate electrode of the n-channel MOS transistor 57, and also to the gate electrode of the n-channel MOS transistor 56 byway of the inverter 60. Although the internal power supply voltage VDD′ is supplied to the NOR gate 61 or the inverter 60 as the power supply, since the high potential power supply voltage VCC is supplied to the source electrodes of the p-channel MOS transistors 58, 59, the signal of the internal power supply voltage VDD′ level is converted into the signal IN1 of the high potential power supply voltage VCC level, and then the level-converted signal is transmitted to the internal circuits.

The other input/output buffers 206-n are configured in the same manner.

Here, in regard to the various types of control signals such as the output enabling signal OE and the write enabling signal WE, and the address signals, the microprocessor 10 transmits the data to the SRAM 20, however reversely, the SRAM 20 will not transmit the data to the microprocessor 10. Therefore, the SRAM 20 may eliminate the output buffers and possess only the input buffers, with regard to the buffers corresponding to the terminals (pads) that take in the various control signals such as the output enabling signal OE and the write enabling signal WE, and the address signals.

The above embodiment exhibits the following functions and effects.

(1) The SRAM 20 takes in the high potential power supply voltage VDD used as the core voltage (VDD) of the microprocessor 10 as the reference voltage, and generates the internal power supply voltage VDD′ that is substantially equal to the high potential power supply voltage VDD; and the internal power supply voltage VDD′ is supplied to the input/output buffer 206 for memory side as the operational power supply voltage. Therefore, in the input/output buffer 103 for system side of the microprocessor 10, the level shifting becomes unnecessary, which makes it possible to couple the input/output buffer 206 for memory side with the bus 106 of the microprocessor 10 through the input/output buffer 103 for system side of a comparably simple configuration. Accordingly, the embodiment achieves a speed-up of the signals exchanged between the microprocessor 10 and the SRAM 20, compared to the conventional circuit in which both the microprocessor 10 and the SRAM 20 execute the level shifting of the signals.

(2) Since the SRAM 20 generates the internal power supply voltage VDD′ substantially equal to the high potential power supply voltage VDD, using the core voltage (VDD) of the microprocessor 10 as the reference voltage, even if the core voltage (VDD) of the microprocessor 10 is changed, the interface level between microprocessor 10 and the SRAM 20 will be matched; thus, the SRAM 20 possesses the flexibility to the diversification of types of the microprocessor 10.

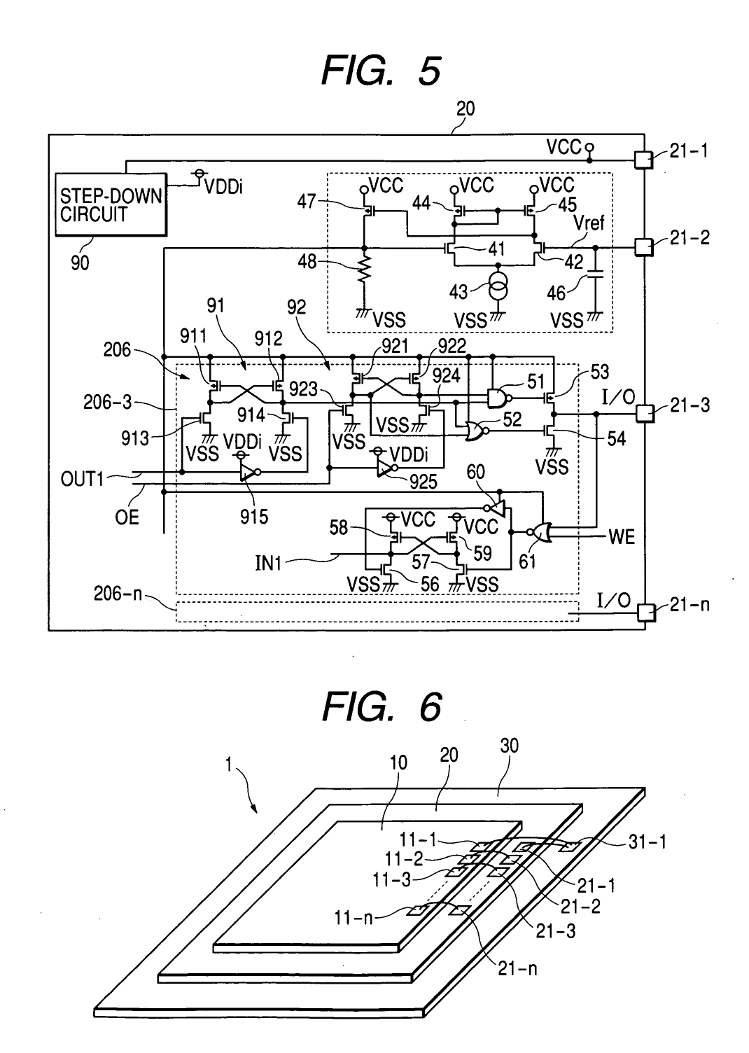

FIG. 5 illustrates another circuit configuration of the SRAM 20.

The SRAM 20 illustrated in FIG. 5 greatly differs from the one illustrated in FIG. 1 in the following points. That is, the former is provided with a step-down circuit 9 that steps down the high potential power supply voltage VCC to thereby generate an internal power supply voltage VDDi, and is also provided with a level shifting circuit that shifts the signal level of the internal power supply voltage VDDi system into that of the internal power supply voltage VDD′ system.

The internal power supply voltage VDDi is set to a lower voltage than the internal power supply voltage VDD′. When the internal power supply voltage VDD′ is set to 1.5 V, the internal power supply voltage VDDi is set to 1.3 V, which is not specifically restricted. The internal circuits of the SRAM 20, such as the row decoder 202, controller 203, column selection circuit 204, and column decoder 205 and so forth, become operational with the supply of the internal power supply voltage VDDi.

The input/output buffer 206 for memory side includes plural input/output buffers 206-3 to 206-n corresponding to the plural bonding pads 21-3 to 21-n. The input/output buffer 206-3 being one of them is configured as follows.

The input/output buffer 206-3 illustrated in FIG. 5 greatly differs from the one illustrated in FIG. 1 in the following points. That is, the former is provided with a level shifting circuit 91 that shifts the signal level of the output signal OUT1 into that of the internal power supply voltage VDD′ system, and a level shifting circuit 92 that shifts the signal level of the output enabling signal OE into that of the internal power supply voltage VDD′ system. The level shifting circuit 91 is configured to include an inverter 915 that inverts a logic of the output signal OUT1, p-channel MOS transistors 911, 912, and n-channel MOS transistors 913, 914. The p-channel MOS transistor 911 and the n-channel MOS transistor 913 are connected in series, and the p-channel MOS transistor 912 and the n-channel MOS transistor 914 are connected in series. The source electrodes of the p-channel MOS transistors 911, 912 are connected to the internal power supply voltage VDD′. The source electrodes of the n-channel MOS transistors 913, 914 are connected to the low potential power supply voltage VSS. The series connection node of the p-channel MOS transistor 912 and the n-channel MOS transistor 914 is connected to the gate electrode of the p-channel MOS transistor 911, and also connected to the input terminal of the NAND gate 51 and the input terminal of the NOR gate 52. The series connection node of the p-channel MOS transistor 911 and the n-channel MOS transistor 913 is connected to the gate electrode of the p-channel MOS transistor 912. Thereby, the signal level of the output signal OUT1 is shifted from the signal level of the internal power supply voltage VDDi system into that of the internal power supply voltage VDD′ system.

The level shifting circuit 92 is configured to include an inverter 925 that inverts a logic of the output enabling signal OE, p-channel MOS transistors 921, 922, and n-channel MOS transistors 923, 924. The p-channel MOS transistor 921 and the n-channel MOS transistor 923 are connected in series, and the p-channel MOS transistor 922 and the n-channel MOS transistor 924 are connected in series. The source electrodes of the p-channel MOS transistors 921, 922 are connected to the internal power supply voltage VDD′. The source electrodes of the n-channel MOS transistors 923, 924 are connected to the low potential power supply voltage VSS. The series connection node of the p-channel MOS transistor 922 and the n-channel MOS transistor 924 is connected to the gate electrode of the p-channel MOS transistor 921, and also connected to the input terminal of the NAND gate 51. The series connection node of the p-channel MOS transistor 921 and the n-channel MOS transistor 923 is connected to the gate electrode of the p-channel MOS transistor 922, and also connected to the input terminal of the NOR gate 52. Thereby, the signal level of the output enabling signal OE is shifted from the signal level of the internal power supply voltage VDDi system into that of the internal power supply voltage VDD′ system.

As mentioned in the above case, when the internal power supply voltage VDDi supplied to the internal circuits of the SRAM 20 is set to a lower level than the internal power supply voltage VDD′, the input/output buffer 206 for memory side only needs to contain the level shifting circuits 91, 92 to shift the signal level of the internal power supply voltage VDDi system into that of the internal power supply voltage VDD′ system. This configuration will also exhibit the same function and effect as the one illustrated in FIG. 1.

FIG. 6 illustrates another configuration of the multi-chip module 1.

A great difference of the multi-chip module 1 illustrated in FIG. 6 from the one illustrated in FIG. 2 lies in that the bonding pad for the high potential power supply voltage VDD is eliminated from the substrate 30, and the bonding pad 11-2 on the microprocessor 10 is bonded to the bonding pad 21-2 on the SRAM 20 by a bonding wire.

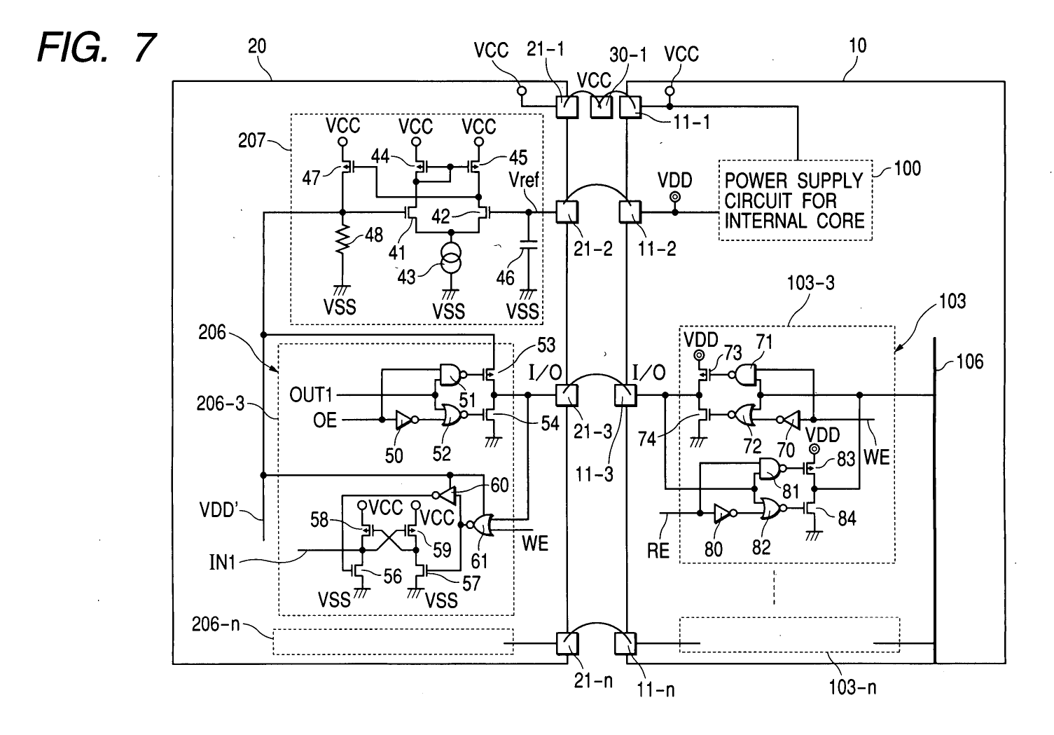

FIG. 7 illustrates a major part of the microprocessor 10 and the SRAM 20 illustrated in FIG. 6.

A great difference of the microprocessor 10 illustrated in FIG. 7 from the one illustrated in FIG. 1 lies in that the microprocessor 10 contains an internal core power supply circuit 100 to generate the high potential power supply voltage VDD by stepping down the high potential power supply voltage VCC. The high potential power supply voltage VCC is set to 3.3 V, and the internal core power supply voltage VDD is set to 1.5 V, which is not specifically restricted. The internal core power supply voltage VDD is supplied to the internal cores (internal circuits) such as the CPU 101, ROM 102, DMAC 104, BSC 105, etc., as illustrated in FIG. 3, and the input/output buffer 103 for system side.

The internal core power supply voltage VDD generated by internal core power supply circuit 100 is transmitted to the internal power supply circuit 207 as the reference voltage Vref through the bonding pad 11-2 on the microprocessor 10 and the bonding pad 21-2 on the SRAM 20. Thus, the configuration illustrated in FIG. 1 transmits the reference voltage Vref through the bonding pad 30-2 on the substrate 30, however the configuration illustrated in FIG. 7 uses the voltage as the reference voltage Vref that the internal core power supply circuit 100 in the microprocessor 10 generates.

The other configuration is the same as the one illustrated in FIG. 1.

The configuration using the core voltage (VDD) generated by the internal core power supply circuit 100 in the microprocessor 10 as the reference voltage Vref also exhibits the same function and effect as the one illustrated in FIG. 1.

When the core voltage (VDD) generated by the internal core power supply circuit 100 in the microprocessor 10 is transmitted to the SRAM 20, it is conceivable to directly supply the core voltage (VDD) to the input/output buffer 206 for memory side. However, if the internal core power supply circuit 100 in the microprocessor 10 does not possess sufficient current capacity, there is a possibility that the core voltage (VDD) decreases the voltage level undesirably. In contrast to this, as shown in FIG. 7, when the voltage generated by the internal core power supply circuit 100 in the microprocessor 10 is taken in as the reference voltage Vref, and based on the voltage, the internal power supply voltage VDD′ is generated by the internal power supply circuit 207, the consumption of the reference voltage Vref itself is extremely insignificant; therefore, even if the internal core power supply circuit 100 in the microprocessor 10 does not possess sufficient current capacity, it is possible to avoid decreasing the voltage level of the core voltage (VDD) undesirably, which is advantageous.

The embodiments being described with concrete configurations, the invention is not restricted to them, and it should be well understood that various changes and modifications are possible without a departure from the sprits and scopes of the invention.

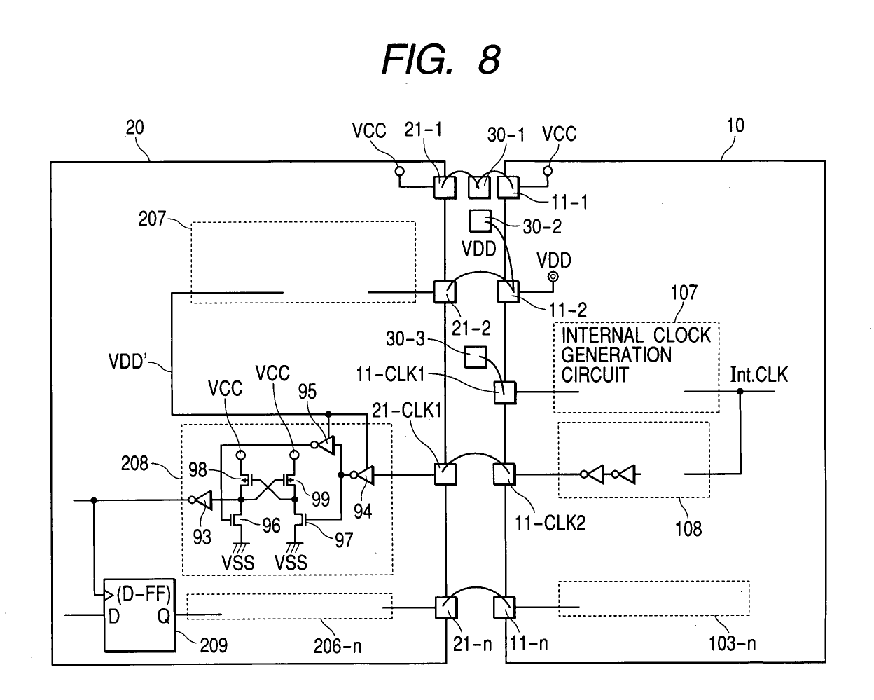

For example, it is possible to supply a clock signal to the SRAM 20 from the microprocessor 10, and to operate the major part of the SRAM 20 synchronously with the clock signal. In this case, the SRAM 20 is made to synchronize with the clock. As shown in FIG. 8, for example, the microprocessor 10 contains an internal clock generator 107 and a clock driver 108. The internal clock generator 107 generates an internal clock signal int. CLK on the basis of a clock signal taken in through a bonding pad 30-3 provided on the substrate 30 (refer to FIG. 2) and a bonding pad 11-CLK1 provided on the microprocessor 10. The internal clock signal int. CLK is supplied to the internal circuits in the microprocessor 10, and is also transmitted to the clock driver 108. The clock driver 108 drives an external load on the basis of the transmitted internal clock signal int. CLK. Thereby, the internal clock signal int. CLK is transmitted to the internal circuits of the SRAM 20 through a bonding pad 11-CLK2 on the microprocessor 10 and a bonding pad 21-CLK1 on the SRAM 20.

The SRAM 20 possesses an input buffer 208 for the clock signal, and a D-type flip-flop 209 to operate synchronously with the clock signal having been buffered by the input buffer 208 for the clock signal. The signal being transmitted from the microprocessor 10 to the SRAM 20 is synchronized with the clock signal in the D-type flip-flop 209, thereafter transmitted to an output buffer of the input/output buffer 206 for memory side, and then transmitted to the microprocessor 10 through the output buffer.

The input buffer 208 includes inverters 93, 94, 95, P-channel MOS transistors 98, 99, and n-channel MOS transistors 96, 97, etc.

The p-channel MOS transistor 98 and the n-channel MOS transistor 96 are connected in series, and the p-channel MOS transistor 99 and the n-channel MOS transistor 97 are connected in series. The source electrodes of the p-channel MOS transistors 98, 99 are connected to the high potential power supply voltage VCC. The source electrodes of the n-channel MOS transistors 96, 97 are connected to the low potential power supply voltage VSS. The series connection node of the p-channel MOS transistor 98 and the n-channel MOS transistor 96 is connected to the gate electrode of the p-channel MOS transistor 99, and also connected through the inverter 93 to the internal circuits and the D-type flip-flop 209.

The series connection node of the p-channel MOS transistor 99 and the n-channel MOS transistor 97 is connected to the gate electrode of the p-channel MOS transistor 98. The output signal from the inverter 94 is transmitted to the gate electrode of the n-channel MOS transistor 97, and also to the gate electrode of the n-channel MOS transistor 96 by way of the inverter 95. Although the internal power supply voltage VDD′ is supplied to the inverters 94, 95 as the power supply, since the high potential power supply voltage VCC is supplied to the source electrodes of the p-channel MOS transistors 98, 99, the signal of the internal power supply voltage VDD′ level is converted into the signal of the high potential power supply voltage VCC level, and then the level-converted signal is transmitted to the internal circuits and the D-type flip-flop 209. Thereby, the internal circuits and the D-type flip-flop 209 are operated to synchronize with the internal clock int. CLK being used in the microprocessor 10.

The invention being described with a configuration in which a microprocessor and an SRAM are stacked up, it is also applicable to a configuration in which a microprocessor and a semiconductor memory such as an SRAM are arranged two-dimensionally in a plane.

The invention is applicable to a device on the condition that the device at least includes a microprocessor and a semiconductor memory capable of being accessed by the microprocessor.

The effect attained by the invention is as follows.

To take a power supply voltage for a microprocessor into a semiconductor memory as a reference voltage, and to supply an internal power supply voltage generated on the basis of the reference voltage to an input/output buffer for memory side will make it possible to match the signal level of the input/output buffer for memory side with that of an input/output buffer for system side; accordingly, the level shifting on the microprocessor side becomes unnecessary, and a high-speed access to the semiconductor memory from the microprocessor becomes possible.

What is claimed is:

1. A semiconductor device in which a microprocessor is coupled with a semiconductor memory capable of being accessed by the microprocessor,
wherein the microprocessor comprises an input/output buffer for system side that is made capable of exchanging signals with the outside by being supplied with a power supply voltage,
wherein the semiconductor memory comprises:
an internal power supply circuit that takes in the power supply voltage as a reference voltage, and generates an internal power supply voltage being substantially equal to the power supply voltage; and
an input/output buffer for memory side that is made capable of exchanging signals with the input/output buffer for system side by being supplied with the internal power supply voltage.

2. A semiconductor device according to claim 1,
wherein the semiconductor memory comprises a dedicated external terminal for taking in the power supply voltage as the reference voltage.

3. A semiconductor device according to claim 2,
wherein the microprocessor comprises internal circuits that are put in operation by being supplied with the power supply voltage.

4. A semiconductor device according to claim 3,
wherein the internal power supply circuit comprises:
a differential-circuit that compares the power supply voltage taken in with an output voltage of the internal power supply circuit; and
a voltage output circuit that determines a level of the internal power supply voltage on the basis of a comparison result in the differential circuit.

5. A semiconductor device according to claim 4,
wherein the semiconductor memory comprises a memory internal circuit that is put in operation by being supplied with a second internal power supply voltage of a higher level than the internal power supply voltage, and
wherein the input/output buffer for memory side comprises a level shifting circuit capable of shifting a signal level of the internal power supply voltage into a signal level of the second internal power supply voltage.

6. A semiconductor device according to claim 4,
wherein the semiconductor memory comprises:
a step-down circuit that generates a third internal power supply voltage of a lower level than the internal power supply voltage; and
a memory internal circuit that is put in operation by being supplied with the third internal power supply voltage, and
wherein the input/output buffer for memory side comprises a level shifting circuit capable of shifting a signal level of the third internal power supply voltage into a signal level of the internal power supply voltage.

7. A semiconductor device in which a microprocessor is coupled with a semiconductor memory capable of being accessed by the microprocessor,
wherein the microprocessor comprises:
an internal core power supply circuit that steps down a power supply voltage externally supplied to thereby generate an internal core power supply voltage; and
an input/output buffer for system side that is made capable of exchanging signals with the outside by being supplied with the internal core power supply voltage, and
wherein the semiconductor memory comprises:
an internal power supply circuit that takes in the internal core power supply voltage as a reference voltage, and generates an internal power supply voltage being substantially equal to the internal core power supply voltage; and
an input/output buffer for memory side that is made capable of exchanging signals with the input/output buffer for system side by being supplied with the internal power supply voltage.

8. A semiconductor device according to claim 7,
wherein the semiconductor memory comprises a dedicated external terminal for taking in the internal core power supply voltage as the reference voltage.

9. A semiconductor device according to claim 8,
wherein the microprocessor comprises internal circuits that are put in operation by being supplied with the power supply voltage.

10. A semiconductor device according to claim 9,
wherein the internal power supply circuit comprises:
a differential circuit that compares the power supply voltage taken in through the external terminal with an output voltage of the internal power supply circuit; and
a voltage output circuit that determines a level of the internal power supply voltage on the basis of a comparison result in the differential circuit.

11. A semiconductor device according to claim 7,
wherein the microprocessor comprises a clock driver capable of outputting a clock signal, and
wherein the semiconductor memory comprises:
a clock buffer that takes in the clock signal outputted through the clock driver in the microprocessor; and
a logic circuit that operates synchronously with the clock signal taken in through the clock buffer.

12. A semiconductor device according to any of claim 1 through claim 11,
wherein the microprocessor and the semiconductor memory are each formed in separate chips, and these chips are integrally packaged by a resin mold.
